(19) United States
(12) Patent Application Publication
(10) Pub. No.: US 2010/0025671 A1
(43) Pub. Date: Feb. 4, 2010

(54) ELECTROLUMINESCENT DEVICES

(75) Inventors: Poopathy Kathirgamanathan, North Harrow (GB); Arumugam Parheepan, Surrey (GB); Muttulingam Kumaraverl, Ealing (GB); Subramaniam Ganeshamurugan, London (GB); Sivagnanasundram Surendrakumar, Middlesex (GB)

Correspondence Address: CONNOLLY BOVE LODGE & HUTZ, LLP, P O BOX 2207, WILMINGTON, DE, 19899, US

(73) Assignee: Merck Patent GmbH, Damstadt (DE)

(21) Appl. No.: 12/520,560

(22) PCT Filed: Dec. 4, 2007
(86) PCT No.: PCT/GB07/50737

§ 371 Date: Jun. 22, 2009

(30) Foreign Application Priority Data
Dec. 22, 2006 (GB) 0625541.8

(51) Int. Cl. H01L 51/54; H01L 51/56

(52) U.S. Cl. 257/40; 438/46; 257/E51.026; 257/E51.022

(57) ABSTRACT

The invention relates to an optical light emitting diode device having an electroluminescent layer and an electron transport layer, wherein the electron transport layer contains zirconium or hafnium quinolate for slowing loss of luminance at a given current density with increase of the time for which the device has been operative. The invention also relates to OLEDs, improved efficiency and/or lifetime is obtained by using zirconium or hafnium quino late as electron transport material.

### FIELD OF THE INVENTION

This invention relates to optical light emitting devices and to methods for improving their performance.

### BACKGROUND TO THE INVENTION

Kulkarni et al., Chem. Mater. 2004, 16, 4556-4573 (the contents of which are incorporated herein by reference) have reviewed the literature concerning electron transport materials (ETMs) used to enhance the performance of organic light-emitting diodes (OLEDs). In addition to a large number of organic materials, they discuss metal chelates including aluminium quinolate, which they explain remains the most widely studied metal chelate owing to its superior properties such as high EA (˜−3.0 eV; measured by the present applicants as −2.9 eV) and IP (˜−5.95 eV; measured by the present applicants as about—5.7 eV), good thermal stability (Tg ˜172° C.) and ready deposition of pinhole-free thin films by vacuum evaporation. Aluminium quinolate remains a preferred material both for use as a host to be doped with various fluorescent materials to provide an electroluminescent layer and for use as an electron transport layer.

### SUMMARY OF THE INVENTION

A problem with which invention is concerned is to provide OLEDs of improved performance. A further problem with which the invention is concerned is to provide further materials for use in the electron transport layer of an OLED.

In one aspect, the invention provides an optical light emitting diode device having an electroluminescent layer and an electron transport layer layer, wherein the electron transport layer comprises zirconium quinolate for slowing loss of luminance at a given current density with increase of the time for which the device has been operative.

In another aspect, the invention relates to the use of zirconium quinolate in an electron transport layer of an OLED device for slowing loss of luminance at a given current density with increase of the time for which the device has been operative.

In a further aspect, the invention relates to the use of zirconium or hafnium quinolate in an electron transport layer of an OLED device for increasing the light output for a given applied voltage, the current efficiency for a given luminance and/or the power efficiency for a given luminance.

The invention also provides a method for slowing loss of luminance of an OLED device at a given current density with increase of the time for which the device has been operative, or for increasing the light output for a given applied voltage, the current efficiency for a given luminance and/or the power efficiency for a given luminance, which method comprises using zirconium quinolate as electron transport material for said device.

### DESCRIPTION OF PREFERRED FEATURES

### Cell Structure

The OLEDs of the invention are useful inter alia in flat panel displays and typically comprise an anode and a cathode between which is sandwiched a multiplicity of thin layers including an electroluminescent layer, electron injection and/or transport layer(s), hole injection and/or transport layer(s) and optionally ancillary layers. The layers are typically built up by successive vacuum vapour deposition operations.

A typical device comprises a transparent substrate on which are successively formed an anode layer, a hole injector (buffer) layer, a hole transport layer, an electroluminescent layer, an electron transport layer, an electron injection layer and an anode layer which may in turn be laminated to a second transparent substrate. Top emitting OLED's are also possible in which an aluminium or other metallic substrate carries an ITO layer, a hole injection layer, a hole transport layer, an electroluminescent layer, an electron transport layer, an electron injection layer and an ITO or other transparent cathode, light being emitted through the cathode. A further possibility is an inverted OLED in which a cathode of aluminium or aluminium alloyed with a low work function metal carries successively an electron injection layer, an electron transport layer, an electroluminescent layer, a hole transport layer, a hole injection layer and an ITO or other transparent conductive anode, emission of light being through the anode. If desired a hole blocking layer may be inserted e.g. between the electroluminescent layer and the electron transport layer.

OLEDs of the invention include small molecule OLEDs, polymer light emitting diodes (p-OLEDs), OLEDs that emit light by fluorescence, OLEDs that emit light by phosphorescence (PHOLEDs) and OLEDs that emit light by ion fluorescence (rare earth complexes) and include single-colour or multi-colour active or passive matrix displays.

### Anode

In many embodiments the anode is formed by a layer of tin oxide or indium tin oxide coated onto glass or other transparent substrate. Other materials that may be used include antimony tin oxide and indium zinc oxide.

### Hole Injection Materials

A single layer may be provided between the anode and the electroluminescent material, but in many embodiments there are at least two layers one of which is a hole injection layer (buffer layer) and the other of which is a hole transport layer, the two layer structure offering in some embodiments improved stability and device life (see U.S. Pat. No. 4,720,432 (VanSlyke et al., Kodak). The hole injection layer may serve to improve the film formation properties of subsequent organic layers and to facilitate the injection of holes into the hole transport layer.

Suitable materials for the hole injection layer which may be of thickness e.g. 0.1-200 nm depending on material and cell type include hole-injecting porphyrinic compounds—see U.S. Pat. No. 4,356,429 (Tang, Eastman Kodak) e.g. zinc phthalocyanine copper phthalocyanine and ZnTpTP, whose formula is set out below:

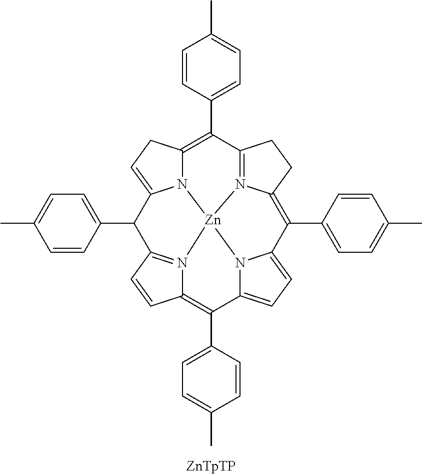

Particularly good device lifetimes may be obtained where the hole transport layer is ZnTpTP and the electron transport layer is zirconium or hafnium quinolate both when the host material for the electroluminescent layer is zirconium or hafnium quinolate and when the host material is aluminium quinolate or another complex or organic small molecule material.

The hole injection layer may also be a fluorocarbon-based conductive polymer formed by plasma polymerization of a fluorocarbon gas—see U.S. Pat. No. 6,208,075 (Hung et al; Eastman Kodak), a triarylamine polymer—see EP-A-0891121 (Inoue et al., TDK Corporation) or a phenylenediamine derivative—see EP-A- 1029909 (Kawamura et al., Idemitsu).

### Hole-Transport Materials

Hole transport layers which may be used are preferably of thickness 20 to 200 nm.

One class of hole transport materials comprises polymeric materials that may be deposited as a layer by means of spin coating. Such polymeric hole-transporting materials include poly(N-vinylcarbazole) (PVK), polythiophenes, polypyrrole, and polyaniline. Other hole transporting materials are conjugated polymers e.g. poly(p-phenylenevinylene) (PPV) and copolymers including PPV. Other preferred polymers are: poly(2,5 dialkoxyphenylene vinylenes e.g. poly(2-methoxy-5-(2-methoxypentyloxy-1,4-phenylene vinylene), poly(2-methoxypentyloxy)-1,4-phenylenevinylene), poly(2-methoxy-5-(2-dodecyloxy-1,4-phenylenevinylene) and other poly(2,5 dialkoxyphenylenevinylenes) with at least one of the alkoxy groups being a long chain solubilising alkoxy group; polyfluorenes and oligofluorenes; polyphenylenes and oligophenylenes; polyanthracenes and oligo anthracenes; and polythiophenes and oligothiophenes.

A further class of hole transport materials comprises sublimable small molecules. For example, aromatic tertiary amines provide a class of preferred hole-transport materials, e.g. aromatic tertiary amines including at least two aromatic tertiary amine moieties (e.g. those based on biphenyl diamine or of a “starburst” configuration), of which the following are representative:

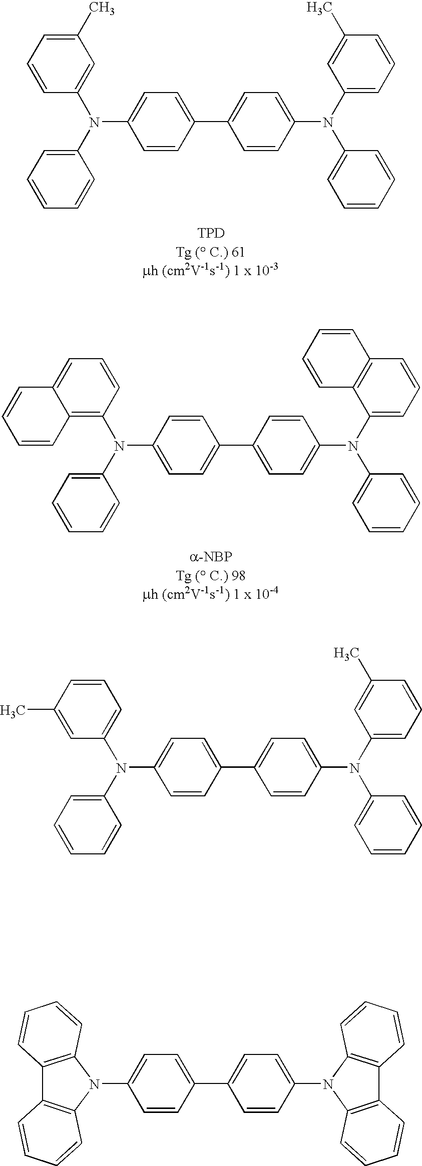

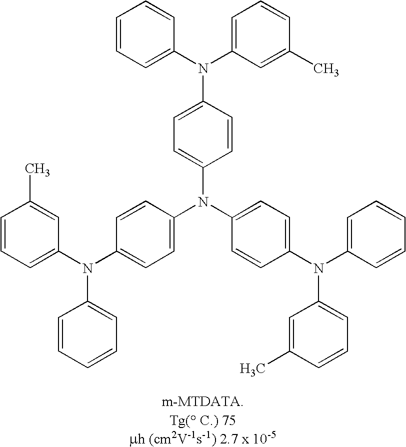

It further includes spiro-linked molecules which are aromatic amines e.g. spiro-TAD (2,2′,7,7′-tetrakis-(diphenylamino)-spiro-9,9′-bifluorene).

A further class of small molecule hole transport materials is disclosed in WO 2006/061594 (Kathirgamanathan et al) and is based on diamino dainthracenes. Typical compounds include:

9-(10-(N-(naphthalen-1-yl)-N-phenylamino)anthracen-9-yl)-N-(naphthalen-1-yl)-N-phenylanthracen-10-amine;

9-(10-(N-biphenyl-N-2-m-tolylamino)anthracen-9-yl)-N-biphenyl-N-2-m-tolylamino-anthracen-10-amine; and

9-( 10-(N-phenyl-N-m-tolylamino)anthracen-9-yl)-N-phenyl-N-m-tolylanthracen-10-amine.

### Electroluminescent Materials

In principle any electroluminescent material may be used, including molecular solids which may be fluorescent dyes e.g. perylene dyes, metal complexes e.g. Alq₃, Ir(III)L₃, rare earth chelates e.g. Tb(III) complexes, dendrimers and oligomers e.g. sexithiophene, or polymeric emissive materials. The electroluminescent layer may comprise as luminescent material a metal quinolate, an iridium, ruthenium, osmium, rhodium, iridium, palladium or platinum complex, a boron complex or a rare earth complex

One preferred class of electroluminescent materials comprises host materials doped with dyes which may be fluorescent, phosphorescent or ion-phosphorescent (rare earth). The term “electroluminescent device” includes an electrophosphorescent device.

Preferably the host is doped with a minor amount of a fluorescent material as a dopant, preferably in an amount of 0.01 to 25% by weight of the doped mixture. As discussed in U.S. Pat. No. 4,769,292 (Tang et al., Kodak), the contents of which are included by reference, the presence of the fluorescent material permits a choice from amongst a wide latitude of wavelengths of light emission. In particular, as disclosed in U.S. Pat. No. 4,769,292 by blending with the organo metallic complex a minor amount of a fluorescent material capable of emitting light in response to hole-electron recombination, the hue of the light emitted from the luminescent zone, can be modified. In theory, if a host material and a fluorescent material could be found for blending which have exactly the same affinity for hole-electron recombination, each material should emit light upon injection of holes and electrons in the luminescent zone. The perceived hue of light emission would be the visual integration of both emissions. However, since imposing such a balance of host material and fluorescent materials is limiting, it is preferred to choose the fluorescent material so that it provides the favoured sites for light emission. When only a small proportion of fluorescent material providing favoured sites for light emission is present, peak intensity wavelength emissions typical of the host material can be entirely eliminated in favour of a new peak intensity wavelength emission attributable to the fluorescent material.

While the minimum proportion of fluorescent material sufficient to achieve this effect varies, in no instance is it necessary to employ more than about 10 mole percent fluorescent material, based of host material and seldom is it necessary to employ more than 1 mole percent of the fluorescent material. On the other hand, limiting the fluorescent material present to extremely small amounts, typically less than about 10⁻³ mole percent, based on the host material, can result in retaining emission at wavelengths characteristic of the host material. Thus, by choosing the proportion of a fluorescent material capable of providing favoured sites for light emission, either a full or partial shifting of emission wavelengths can be realized. This allows the spectral emissions of the EL devices to be selected and balanced to suit the application to be served. In the case of fluorescent dyes, typical amounts are 0.01 to 5 wt %, for example 2-3 wt %. In the case of phosphorescent dyes typical amounts are 0.1 to 15 wt %. In the case of ion phosphorescent materials typical amounts are 0.01-25 wt % or up to 100 wt %.

Choosing fluorescent materials capable of providing favoured sites for light emission, necessarily involves relating the properties of the fluorescent material to those of the host material. The host can be viewed as a collector for injected holes and electrons with the fluorescent material providing the molecular sites for light emission. One important relationship for choosing a fluorescent material capable of modifying the hue of light emission when present in the host is a comparison of the reduction potentials of the two materials. The fluorescent materials demonstrated to shift the wavelength of light emission have exhibited a less negative reduction potential than that of the host. Reduction potentials, measured in electron volts, have been widely reported in the literature along with varied techniques for their measurement. Since it is a comparison of reduction potentials rather than their absolute values which is desired, it is apparent that any accepted technique for reduction potential measurement can be employed, provided both the fluorescent and host reduction potentials are similarly measured. A preferred oxidation and reduction potential measurement techniques is reported by R. J. Cox, Photographic Sensitivity, Academic Press, 1973, Chapter 15.

A second important relationship for choosing a fluorescent material capable of modifying the hue of light emission when present in the host is a comparison of the band-gap potentials of the two materials. The fluorescent materials demonstrated to shift the wavelength of light emission have exhibited a lower band gap potential than that of the host. The band gap potential of a molecule is taken as the potential difference in electron volts (eV) separating its ground state and first singlet state. Band gap potentials and techniques for their measurement have been widely reported in the literature. The band gap potentials herein reported are those measured in electron volts (eV) at an absorption wavelength which is bathochromic to the absorption peak and of a magnitude one tenth that of the magnitude of the absorption peak. Since it is a comparison of band gap potentials rather than their absolute values which is desired, it is apparent that any accepted technique for band gap measurement can be employed, provided both the fluorescent and host band gaps are similarly measured. One illustrative measurement technique is disclosed by F. Gutman and L. E. Lyons, Organic Semiconductors, Wiley, 1967, Chapter 5.

With host materials which are themselves capable of emitting light in the absence of the fluorescent material, it has been observed that suppression of light emission at the wavelengths of emission characteristics of the host alone and enhancement of emission at wavelengths characteristic of the fluorescent material occurs when spectral coupling of the host and fluorescent material is achieved. By “spectral coupling” it is meant that an overlap exists between the wavelengths of emission characteristic of the host alone and the wavelengths of light absorption of the fluorescent material in the absence of the host. Optimal spectral coupling occurs when the emission wavelength of the host is within ±25 nm of the maximum absorption of the fluorescent material alone. In practice advantageous spectral coupling can occur with peak emission and absorption wavelengths differing by up to 100 nm or more, depending on the width of the peaks and their hypsochromic and bathochromic slopes. Where less than optimum spectral coupling between the host and fluorescent materials is contemplated, a bathochromic as compared to a hypsochromic displacement of the fluorescent material produces more efficient results.

Useful fluorescent materials are those capable of being blended with the host and fabricated into thin films satisfying the thickness ranges described above forming the luminescent zones of the EL devices of this invention. While crystalline organometallic complexes do not lend themselves to thin film formation, the limited amounts of fluorescent materials present in the host permit the use of fluorescent materials which are alone incapable of thin film formation. Preferred fluorescent materials are those which form a common phase with the host. Fluorescent dyes constitute a preferred class of fluorescent materials, since dyes lend themselves to molecular level distribution in the host. Although any convenient technique for dispersing the fluorescent dyes in the host can be used, preferred fluorescent dyes are those which can be vacuum vapour deposited along with the host materials.

One class of host materials comprises metal complexes e.g. metal quinolates such as lithium quinolate, aluminium quinolate, titanium quinolate, zirconium quinolate or hafnium quinolate which may be doped with fluorescent materials or dyes as disclosed in patent application WO 2004/058913.

In the case of quinolates e.g. aluminium quinolate:
(a) the compounds below, for example, can serve as red dopants:

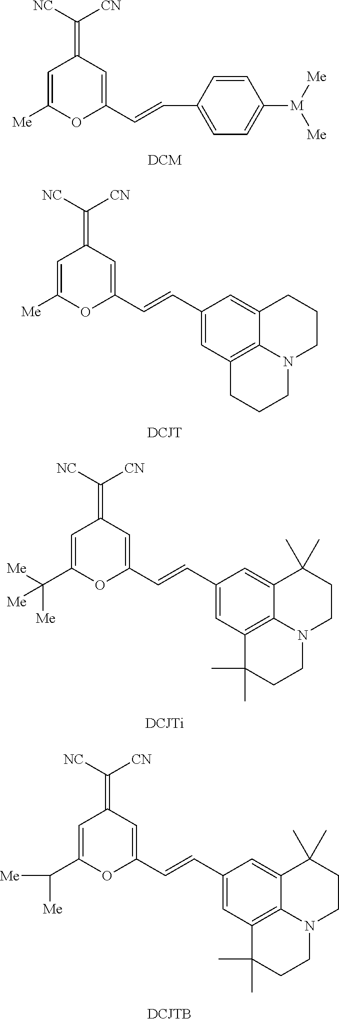

(b) the compounds below, for example can serve as green dopants:

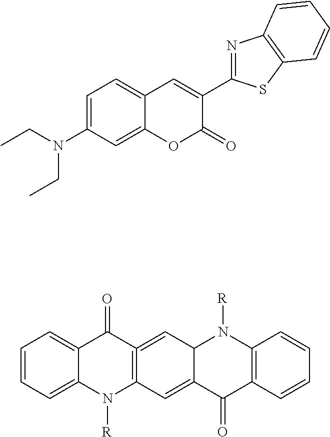

wherein R is C₁-C₄ alkyl, monocyclic aryl, bicycic aryl, monocyclic heteroaryl, bicyclic heteroaryl, aralkyl or thienyl, preferably phenyl; and
(c) for biphenyloxy aluminium bis-quinolate (BAlQ₂) or aluminium quinolate the compounds perylene and 9-(10-(N-(naphthalen-8-yl)-N-phenylamino)anthracen-9-yl)-N-(naphthalen-8-yl)-N-phenylanthracen-10-amine can serve as a blue dopants.

Another preferred class of hosts is small molecules incorporating conjugated aromatic systems with e.g. 4-10 aryl or heteroaryl rings which may bear substituents e.g. alkyl (especially methyl), alkoxy and fluoro and which may also be doped with fluorescent materials or dyes.

An example of a system of the above kind is a blue-emitting material based on the following compound as host

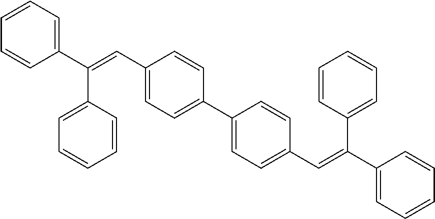

and perylene or 9-(10-(N-(naphthalen-8-yl)-N-phenylamino)anthracen-9-yl)-N-(naphthalen-8-yl)-N-phenylanthracen-10-amine as dopant. Further examples of host materials which are small aromatic molecules are shown below:

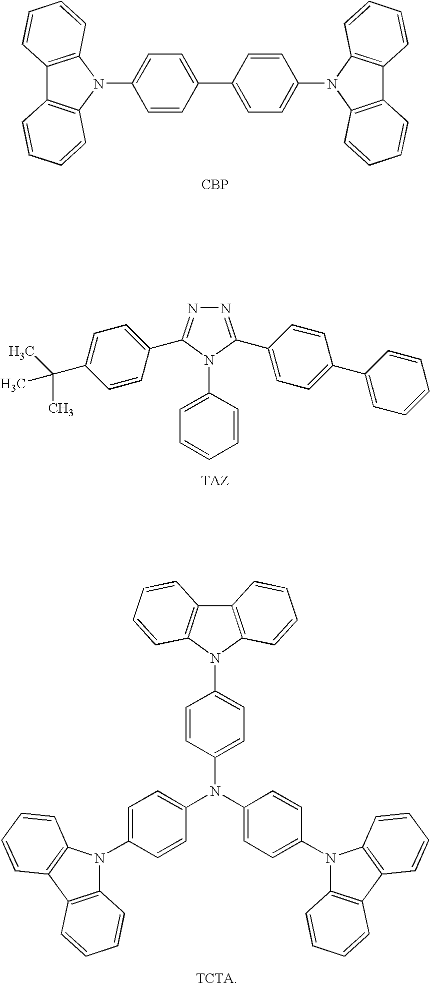

Blue-emitting materials may be based on an organic host (e.g. a conjugated aromatic compound as indicated above) and diarylamine anthracene compounds disclosed in WO 2006/090098 (Kathirgamanathan et al.) as dopants. For example, CBP may be doped with blue-emitting substituted anthracenes inter alia

9,10-bis(-4-methylbenzyl)-anthracene,

9,10-bis-(2,4-dimethylbenzyl)-anthracene,

9,10-bis-(2,5-dimethylbenzyl)-anthracene,

1,4-bis-(2,3,5,6-tetramethylbenzyl)-anthracene,

9,10-bis-(4-methoxybenzyl)-anthracene,

9,10-bis-(9H-fluoren-9-yl)-anthracene,

2,6-di-t-butylanthracene,

2,6-di-t-butyl-9,10-bis-(2,5-dimethylbenzyl)-anthracene,

2,6-di-t-butyl-9,10-bis-(naphthalene-1-ylmethyl)-anthracene.

Further blue-emitting materials may employ TCTA as host and it may be doped with the blue phosphorescent materials set out below, see WO 2005/080526 (Kathirgamanathan et al.):

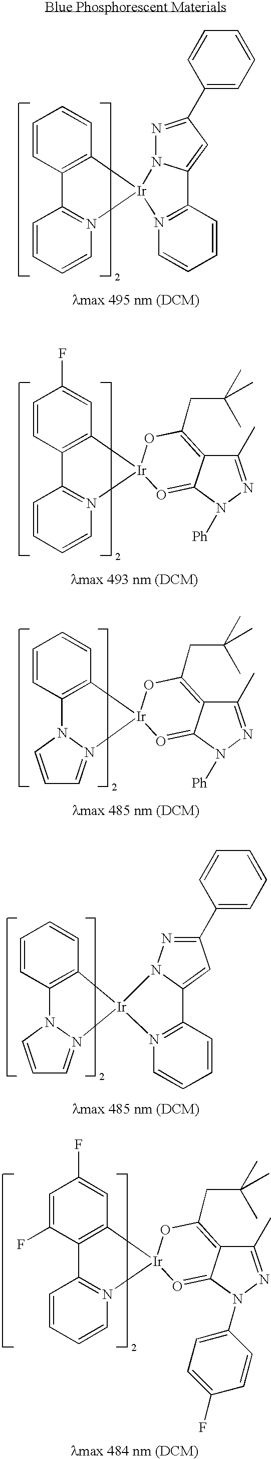

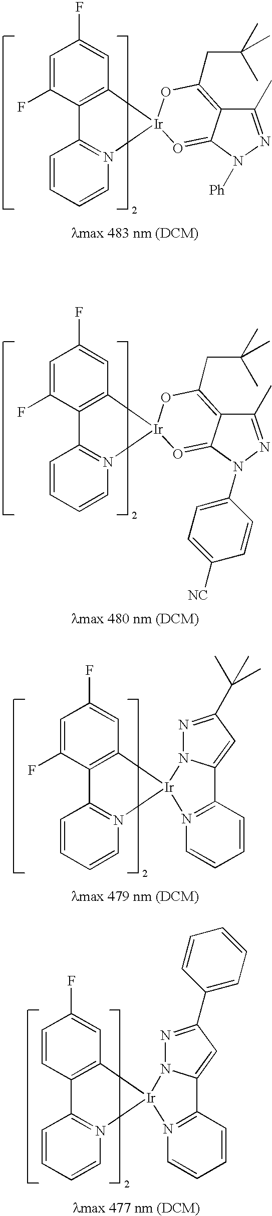

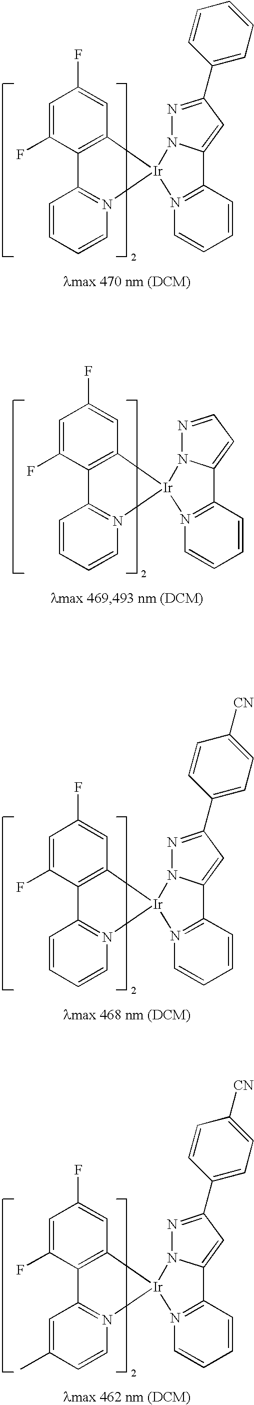

Examples of green phosphorescent materials that may be employed with CBP or TAZ are set out below (see WO 2005/080526):

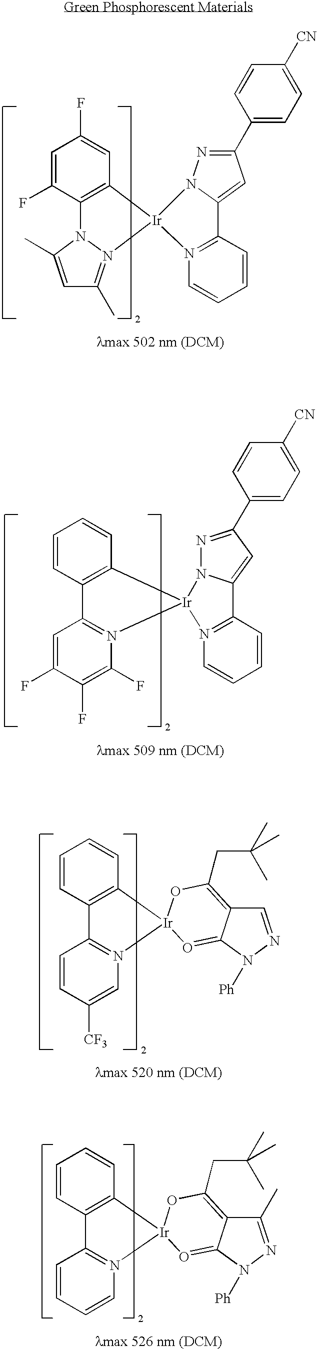

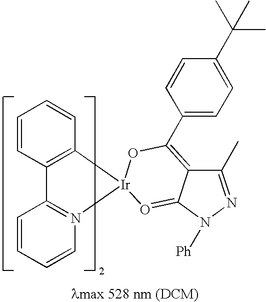

Examples of red phosphorescent materials that may be employed with CBP or TAZ are set out below (see WO 2005/080526):

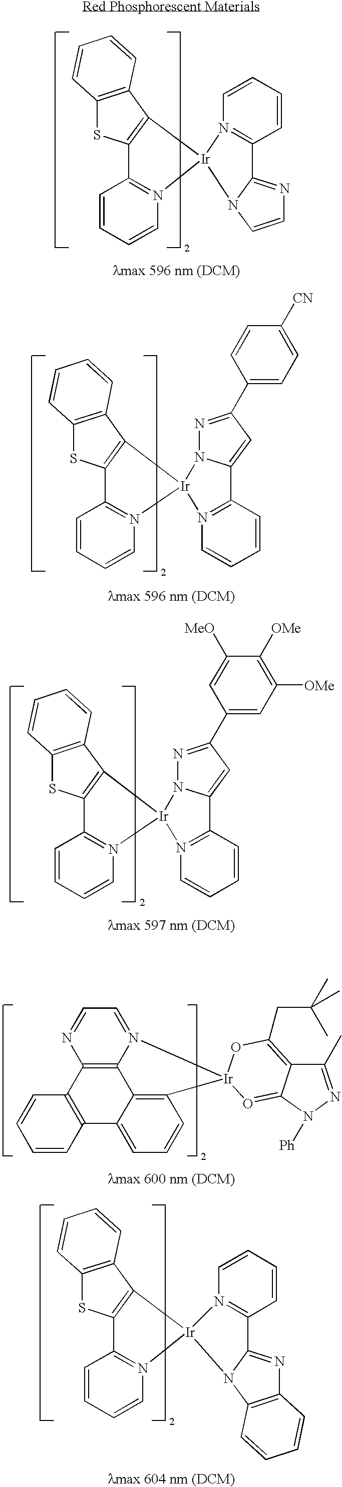

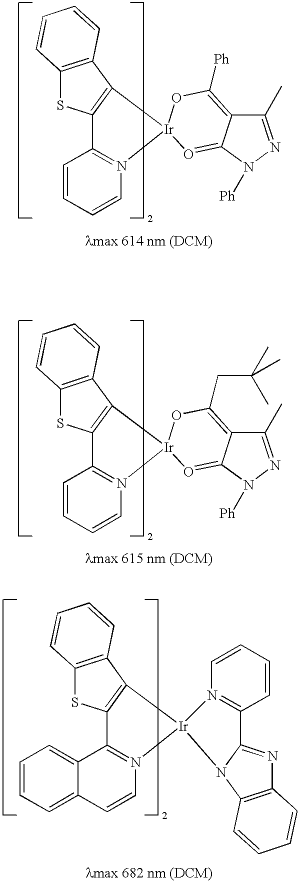

As further dopants, fluorescent laser dyes are recognized to be particularly useful fluorescent materials for use in the organic EL devices of this invention. Dopants which can be used include diphenylacridine, coumarins, perylene and their derivatives. Useful fluorescent dopants are disclosed in U.S. Pat. No. 4,769,292. One class of preferred dopants is coumarins. The following are illustrative fluorescent coumarin dyes known to be useful as laser dyes:

FD-1 7-Diethylamino-4-methylcoumarin,

FD-2 4,6-Dimethyl-7-ethylaminocoumarin,

FD-3 4-Methylumbelliferone,

FD-4 3-(2′-Benzothiazolyl)-7-diethylamino coumarin,

FD-5 3-(2′-Benzimidazolyl)-7-N,N-diethylaminocoumarin,

FD-6 7-Amino-3-phenylcoumarin,

FD-7 3-(2′-N-Methylbenzimidazolyl)-7-N,Ndiethylaminocoumarin,

FD-8 7-Diethylamino-4-trifluoromethylcoumarin,

FD-9 2,3,5,6-1H,4H-Tetrahydro-8-methylquinolazino[9,9a,1-gh]coumarin,

FD-10 Cyclopenta[c]julolindino[9,10-3]-11H-pyran-11-one,

FD-11 7-Amino-4-methylcoumarin,

FD-12 7-Dimethylamino cyclopenta[c]coumarin,

FD-13 7-Amino-4-trifluoromethylcoumarin,

FD-14 7-Dimethylamino-4-trifluoromethylcoumarin,

FD-15 1,2,4,5,3H,6H,10H-Tetrahydro-8-trifluoromethyl[1]benzopyrano[9,9a,1-gh]quinolizin-10-one,

FD-16 4-Methyl-7-(sulfomethylamino)coumarin sodium salt,

FD-17 7-Ethylamino-6-methyl-4-trifluoromethylcoumarin,

FD-18 7-Dimethylamino-4-methylcoumarin,

FD-19 1,2,4,5,3H,6H,10H-Tetrahydro-carbethoxy[1]benzopyrano[9,9a,1-gh]quinolizino-10-one,

FD-20 9-Acetyl-1,2,4,5,3H,6H,10H-tetrahydro[1]benzopyrano[9,9a,1-gh]quinolizino-10-one,

FD-2 19-Cyano-1,2,4,5,3H,6H,10H-tetrahydro[1]benzopyrano[9,9a,1-gh]quinolizino-10-one,

FD22 9-(t-Butoxycarbonyl)-1,2,4,5,3H,6H,10H-tetrahyro[1]-benzopyrano-[9,9a,1-gh]quinolizino-10-one,

FD-23 4-Methylpiperidino[3,2-g]coumarin,

FD-24 4-Trifluoromethylpiperidino[3,2-g]coumarin,

FD-25 9-Carboxy-1,2,4,5,3H,6H,10OH-tetrahydro[1]benzopyrano[9,9a,1-gh]quinolizino-10-one,

FD-26 N-Ethyl-4-trifluoromethylpiperidino[3,2-g].

Other dopants include salts of bis benzene sulphonic acid (require deposition by spin-coating rather than sublimation) such as

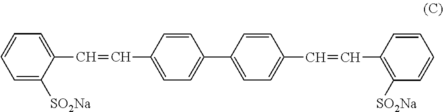

and perylene and perylene derivatives and dopants. Other dopants are dyes such as the fluorescent 4-dicyanomethylene-4H-pyrans and 4-dicyanomethylene-4H-thiopyrans, e.g. the fluorescent dicyanomethylenepyran and thiopyran dyes. Useful fluorescent dyes can also be selected from among known polymethine dyes, which include the cyanines, complex cyanines and merocyanines (i.e. tri-, tetra- and poly-nuclear cyanines and merocyanines), oxonols, hemioxonols, styryls, merostyryls, and streptocyanines. The cyanine dyes include, joined by a methine linkage, two basic heterocyclic nuclei, such as azolium or azinium nuclei, for example, those derived from pyridinium, quinolinium, isoquinolinium, oxazolium, thiazolium, selenazolium, indazolium, pyrazolium, pyrrolium, indolium, 3H-indolium, imidazolium, oxadiazolium, thiadioxazolium, benzoxazolium, benzothiazolium, benzoselenazolium, benzotellurazolium, benzimidazolium, 3H- or 1H-benzoindolium, naphthoxazolium, naphthothiazolium, naphthoselenazolium, naphthotellurazolium, carbazolium, pyrrolopyridinium, phenanthrothiazolium, and acenaphthothiazolium quaternary salts. Other useful classes of fluorescent dyes are 4-oxo-4H-benz-[d,e]anthracenes and pyrylium, thiapyrylium, selenapyrylium, and telluropyrylium dyes.

Further blue-emitting materials are disclosed in the following patents, applications and publications, the contents of which are incorporated herein by reference:

U.S. Pat. No. 5,141,671 (Bryan, Kodak)—Aluminium chelates containing a phenolato ligand and two 8-quinolinolato ligands.

WO 00/32717 (Kathirgamanathan)—Lithium quinolate which is vacuum depositable, and other substituted quinolates of lithium where the substituents may be the same or different in the 2,3,4,5,6 and 7 positions and are selected from alky, alkoxy, aryl, aryloxy, sulphonic acids, esters, carboxylic acids, amino and amido groups or are aromatic, polycyclic or heterocyclic groups.

US 2006/0003089 (Kathirgamanathan)—Lithium quinolate made by reacting a lithium alkyl or alkoxide with 8-hydroxyquinoline in acetonitrile.

Misra, http://www.ursi.org/Proceedings/ProcGA05/pdf/D04.5(01720).pdf Blue organic electroluminescent material bis-(2-methyl 8-quinolinolato)(triphenyl siloxy)aluminium (III) vacuum depositable at 1×10⁻⁵ Torr.

WO 03/006573 (Kathirgamanathan et al)—Metal pyrazolones.

WO 2004/084325 (Kathirgamanathan et al)—Boron complexes.

WO 2005/080526 (Kathitgamanathan et al)—Blue phosphorescent iridium-based complexes.

Ma et al., Chem. Comm. 1998, 2491-2492 Preparation and crystal structure of a tetranuclear zinc(II) compound [Zn₄O(AID)₆] with 7-azaindolate as a bridging ligand. Fabrication of inter alia a single-layer LED by vacuum deposition of this compound (<200° C., 2×10⁻⁶ Torr) onto a glass substrate coated with indium-tin oxide to form a thin homogeneous film was reported.

Further electroluminescent materials which can be used include metal quinolates such as aluminium quinolate, lithium quinolate, titanium quinolate, zirconium quinolate, hafnium quinolate etc.

Many further electroluminescent materials that may be used are disclosed in WO 2004/050793 (pyrazolones), WO 2004/058783 (diiridium metal complexes), WO 2006/016193 (dibenzothiophenyl metal complexes) and WO 2006/024878 (thianthrene metal complexes), see also WO 2006/040593 the contents of which are incorporated herein by reference. Rare earth chelates, in particular may be employed as green and red emitters. Furthermore, there may be used as electroluminescent materials conducting polymers e.g. polyaniline, phenylene vinylene polymers, fluorene homopolymers and copolymers, phenylene polymers, as indicated below:

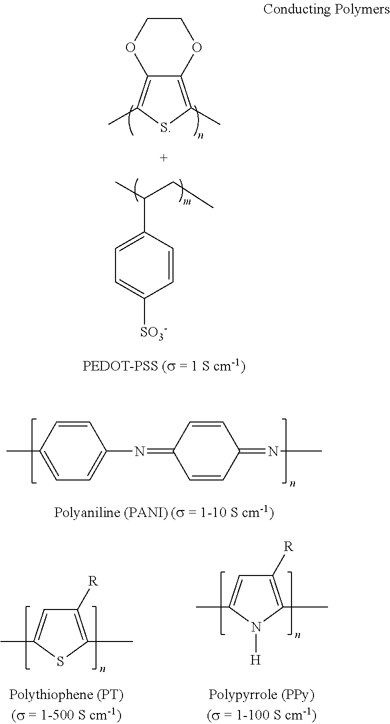

### Electron Transport Material

As explained, the electron transport material used here consists of or comprises zirconium or hafnium quinolate, zirconium quinolate being preferred for many embodiments.

Zirconium quinolate has a particularly advantageous combination of properties for use as an electron transport material and which identify it as being a significant improvement on aluminium quinolate for use as an electron transport material. It has high electron mobility. Its melting point (388° C.) is lower than that of aluminium quinolate (414° C.). It can be purified by sublimation and unlike aluminium quinolate it resublimes without residue, so that it is even easier to use than aluminium quinolate. Its lowest unoccupied molecular orbital (LUMO) is at −2.9 eV and its highest occupied molecular orbital (HOMO) is at −5.6 eV, similar to the values of aluminium quinolate. Furthermore, unexpectedly, it has been found that when incorporated into a charge transport layer it slows loss of luminance of an OLED device at a given current with increase of the time for which the device has been operative (i.e. increases device lifetime), or increases the light output for a given applied voltage, the current efficiency for a given luminance and/or the power efficiency for a given luminance. Embodiments of cells in which the electron transport material is zirconium quinolate can exhibit reduced turn-on voltage and up to four times the lifetime of similar cells in which the electron transport material is zirconium quinolate. It is compatible with aluminium quinolate when aluminium quinolate is used as host in the electroluminescent layer of an OLED, and can therefore be employed by many OLED manufacturers with only small changes to their technology and equipment. It also forms a good electrical and mechanical interface with inorganic electron injection layers e.g. a LiF layer where there is a low likelihood of failure by delamination. Of course zirconium quinolate can be used both as host in the electroluminescent layer and as electron transfer layer. The properties of hafnium quinolate are generally similar to those of zirconium quinolate.

Zirconium or hafnium quinolate may be the totality, or substantially the totality of the electron transport layer. It may be a mixture of co-deposited materials which is predominantly zirconium quinolate. The zirconium or hafnium may be doped as described in GB 06 14847.2 filed 26 Jul. 2006, the contents of which are incorporated herein by reference. Suitable dopants include fluorescent or phosphorescent dyes or ion fluorescent materials e.g. as described above in relation to the electroluminescent layer, e.g. in amounts of 0.01-25 wt % based on the weight of the doped mixture. Other dopants include metals which can provide high brightness at low voltage. Additionally or alternatively, the zirconium or hafnium quinolate may be used in admixture with another electron transport material. Such materials may include complexes of metals in the trivalent or pentavalent state which should further increase electron mobility and hence conductivity. The zirconium and hafnium quinolate may be mixed with a quinolate of a metal of group 1, 2, 3, 13 or 14 of the periodic table, e.g. lithium quinolate or zinc quinolate. Preferably the zirconium or hafnium quinolate comprises at least 30 wt % of the electron transport layer, more preferably at least 50 wt %.

### Electron Injection Material

Any known electron injection material may be used, LiF being typical. Other possibilities include BaF₂, CaF₂, CsF, MgF₂ and KF.

### Cathode

In many embodiments, aluminium is used as the cathode either on its own or alloyed with elements such as magnesium or silver, although in some embodiments other cathode materials e.g. calcium may be employed.. In an embodiment the cathode may comprise a first layer of alloy e.g. Li—Ag, Mg—Ag or Al—Mg closer to the electron injection or electron transport layer and an second layer of pure aluminium further from the electron injection or electron transport layer.

How the invention may be put into effect will now be described with reference to the following examples.

### Preparative Methods

Zirconium tetrakis(8-hydroxyquinolate) (Zrq₄)

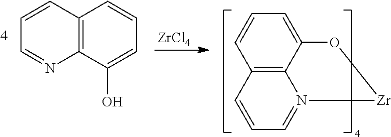

To a solution of 8-Hydroxyquinoline (20.0 g, 138 mmol) in ethanol (300 mL, 95%) was added zirconium (IV) chloride (8.03 g, 34 mmol) in ethanol (50 mL). The pH of the solution was increased by dropwise addition of piperidine (total ˜15 mL, 150 mmol) until a yellow precipitate forms. The suspension was heated to approx. 60° for 1 hour, cooled to room temperature and the precipitate collected onto a Buchner funnel. This was thoroughly washed with ethanol (3×100 mL, 95%) and dried under vacuum. Initial purification was performed by Soxhlet extraction with 1,4-dioxane for 24 hours. Concentration of the 1,4-dioxane yields a yellow precipitate, which was collected on a Buchner funnel and washed with ethanol (100 mL, 95%). This sample was dried in a vacuum oven at 80° C. for 4 hours. Final purification was achieved by sublimation. Yield—75% before sublimation. (60% after 2 sublimations).

Sublimation (390° C., 10⁻⁶ Torr), m.p. 383° C.

Hafnium tetrakis(8-hydroxyquinolate) (Hfq₄)

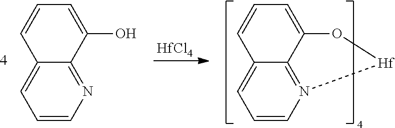

To a solution of 8-Hydroxyquinoline (5.44 g, 37.5 mmol) in ethanol (200 mL, 95%) was added hafnium (IV) chloride (3.0 g, 9.37 mmol) in ethanol (100 mL), followed by a further 300 mL water. The pH of the solution was increased by dropwise addition of piperidine until a yellow precipitate forms. The resulting yellow precipitate was collected and washed with ethanol (100 mL, 95%), water (200 mL) and finally ethanol (100 mL, 95%). The sample was dried under vacuum at 80° C. until no further weight loss was detected.

Sublimation (400° C., 10⁻⁶ Torr) yielded an analytical sample (4.5 g, 64%), m.p. 398° C.

### Device Structure

A pre-etched ITO coated glass piece (10×10cm) was used. The device was fabricated by sequentially forming layers on the ITO, by vacuum evaporation using a Solciet Machine, ULVAC Ltd. Chigasaki, Japan. The active area of each pixel was 3 mm by 3 mm. The coated electrodes were encapsulated in an inert atmosphere (nitrogen) with UV-curable adhesive using a glass back plate. Electroluminescence studies were performed with the ITO electrode was always connected to the positive terminal. The current vs. voltage studies were carried out on a computer controlled Keithly 2400 source meter.

### Example 1

Devices with red, green and blue green emitters were formed by the method described above consisting of an anode layer, buffer layer, hole transport layer, electroluminescent layer (doped metal complex), electron transport layer, electron injection layer and cathode layer, film thicknesses being in nm:

### Green

ITO/ZnTp TP (20)/α-NBP(50)/HOST:DPQA (40:0.1)/ETL (20)/LiF(0.5)/Al wherein DPQA is diphenyl quinacridone and the host and ETL are Alq₃ or Zrq₄.

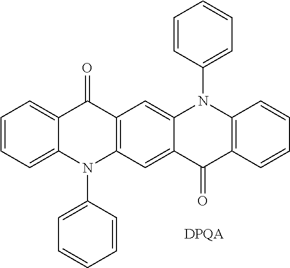

### Red

ITO/ZnTp TP (20)/α-NBP(50)/Alq₃:DCJTi (60:0.6)/ETL (20)/LiF(0.5)/Al wherein the ETL is Alq₃ or Zrq₄.

### Blue

### ITO/HIL/HTL/Host:Blue dopant/ETL/El/Cathode

Wherein HIL, HTL, ETL and EI are self-evident acronyms and ETL represents Alq₃ or Zrq₄.

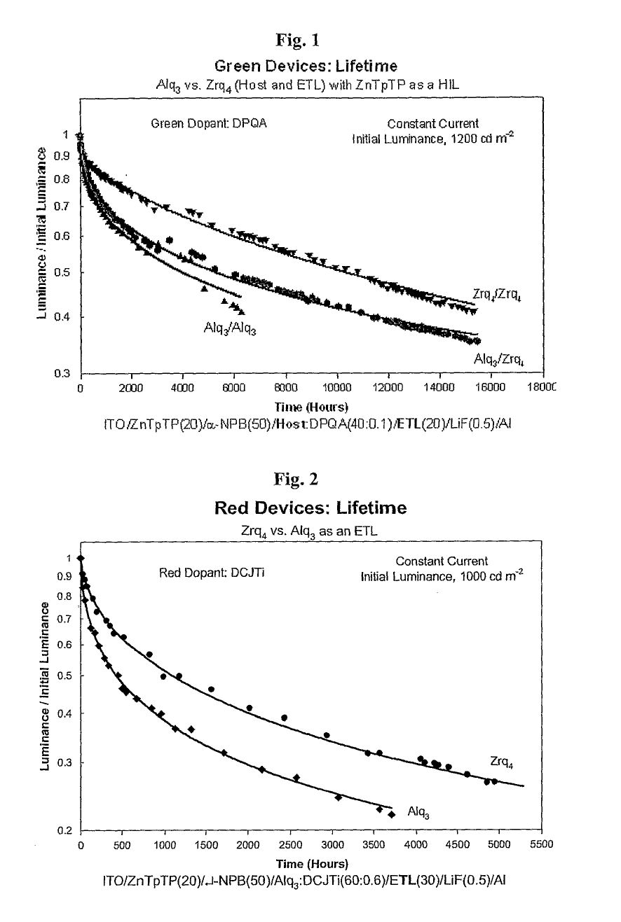

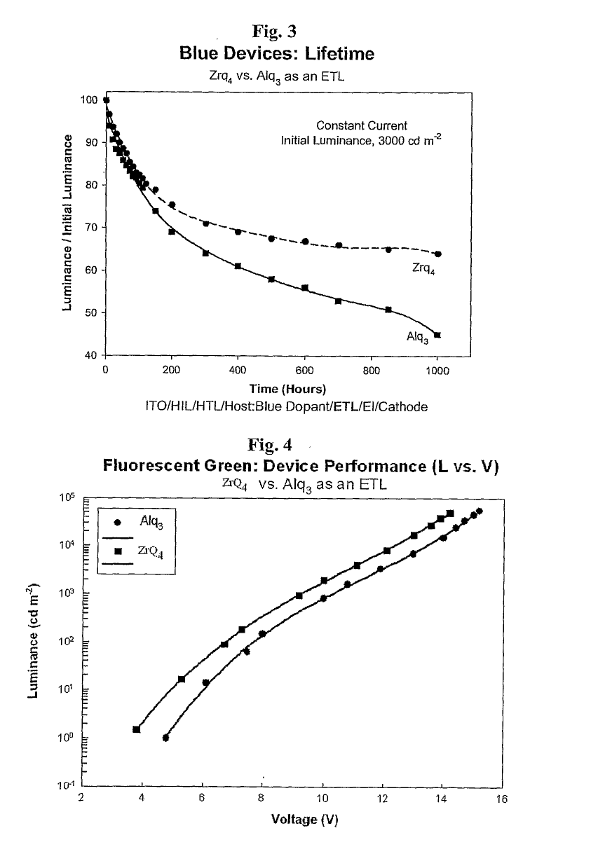

The cells employing zirconium quinolate as electron transport layer exhibited better performance than their counterparts using aluminium quinolate as electron transport layer. The cells using zirconium quinolate as the electron transport layer exhibited significant improvements in efficiency measurable as luminance for a given applied voltage, current efficiency for a given luminance or power efficiency for a given luminance. The change of electron transport material did not give rise to significant change in the emission spectrum of the devices. For many of the devices reductions of operating voltage of up to 50% of the value using an aluminium quinolate electron transport layer were observed, depending on the compositions of the other layers. Results as regards device lifetime are illustrated in the accompanying graphs (FIGS. 1-3).

Similar results were obtained with red and green OLEDs where Alq₃ was the host for the electroluminescent layer and the electron transport layer was Alq₃ or Zrq₄.

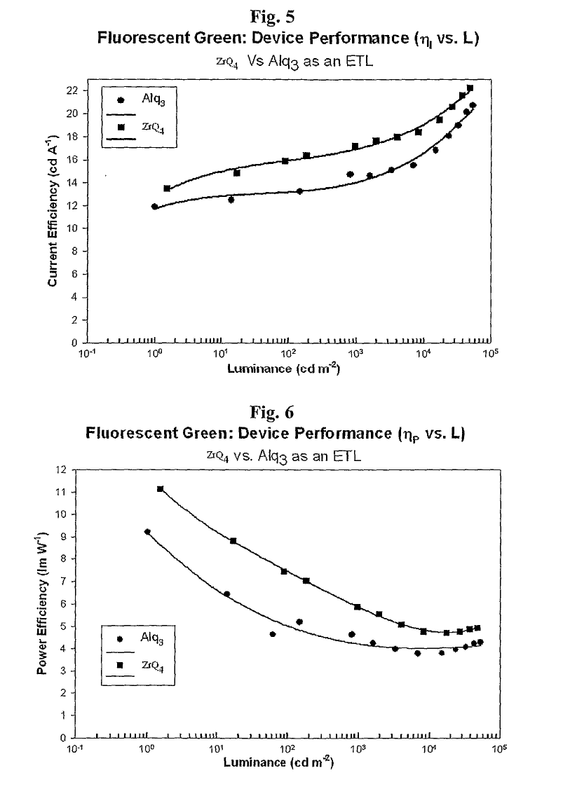

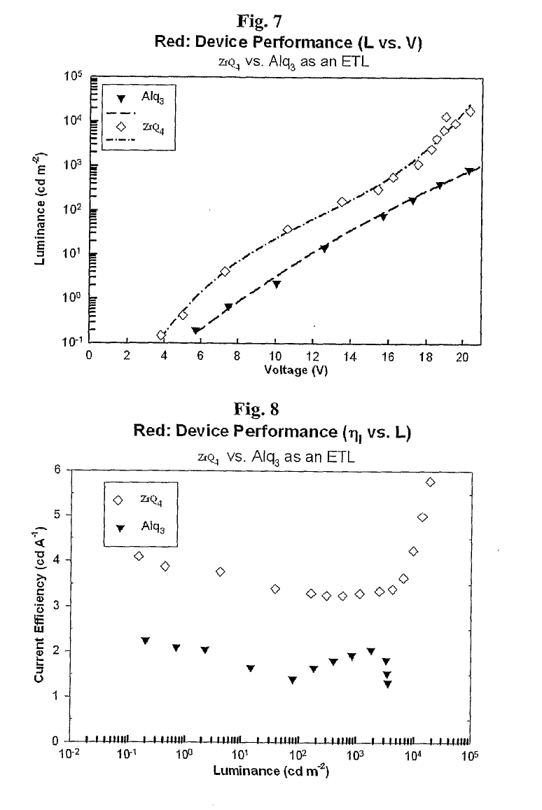

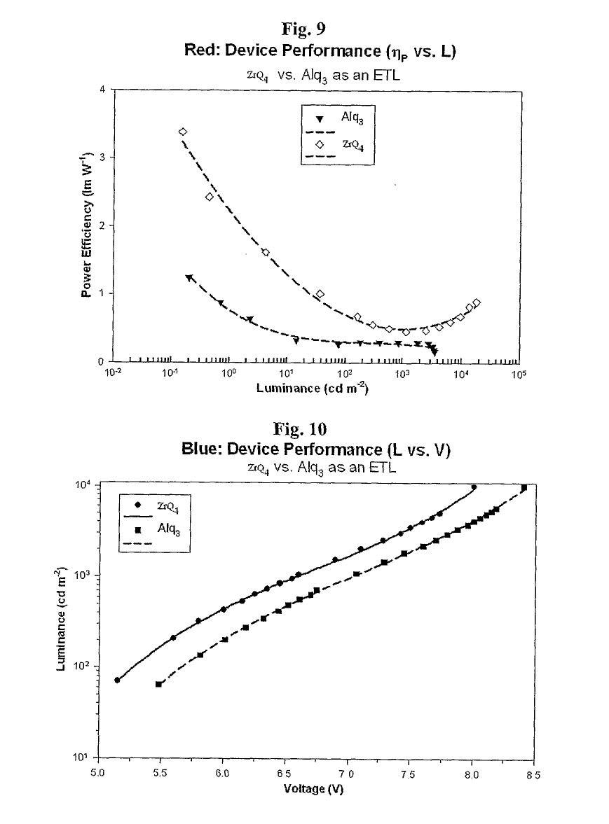

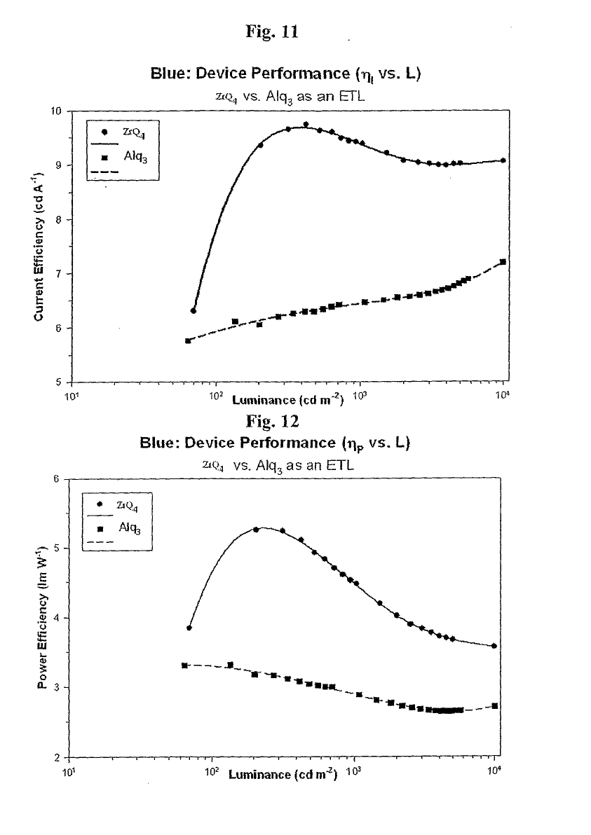

FIGS. 4-12 show characteristic curves for green, red and blue emitter-containing cells similar to those set out above.

### Example 2

Devices were formed similarly to Example 1 but using biphenoxy aluminium bis quinolate (BAlq₂) as host material for the electroluminescent layer, which was doped with blue dopant as in Example 1. The device with the zirconium quinolate electron transport layer (15 nm) exhibited better luminance/voltage characteristics than a similar device using aluminium quinolate and is expected to exhibit greater lifetime.

1-12. (canceled)

13. An optical light emitting diode device having an electroluminescent layer and an electron transport layer, wherein the electron transport layer comprises zirconium or hafnium quinolate for slowing loss of luminance at a given current density with increase of the time for which the device has been operative.

14. The device of claim 13, wherein the electroluminescent layer comprises a metal complex.

15. The device of claim 14, wherein the electroluminescent layer comprises zirconium or hafnium quinolate as a host material doped with a dopant.

16. The device of claim 14, wherein the electroluminescent layer comprises aluminium quinolate as a host material doped with a dopant.

17. The device of claim 13, wherein the electroluminescent layer comprises an aromatic tertiary amine as a host material doped with a dopant.

18. The device of claim 13, wherein the electroluminescent layer comprises a light emitting material which is a metal or metalloid complex.

19. The device of claim 18, wherein the electroluminescent layer comprises as a luminescent material, a metal quinolate, an iridium, ruthenium, osmium, rhodium, iridium, palladium or platinum complex, a boron complex or a rare earth complex.

20. The device of claim 18, wherein the electroluminescent layer comprises as an electroluminescent material, lithium quinolate or aluminium quinolate.

21. The device of claim 13, wherein the electroluminescent layer comprises a light-emitting conjugated polymer or copolymer or a dendrimer.

22. An electron transport layer of an OLED device for slowing loss of luminance at a given current density with increase of the time for which the device has been operative which comprises zirconium or hafnium quinolate.

23. An electron transport layer of an OLED device for increasing the light output for a given applied voltage, the current efficiency for a given luminance and/or the power efficiency for a given luminance which comprises zirconium or hafnium quinolate

24. A method for slowing loss of luminance of an OLED device at a given current density with increase of the time for which the device has been operative, or for increasing the light output for a given applied voltage, the current efficiency for a given luminance and/or the power efficiency for a given luminance, which method comprises using zirconium or hafnium quinolate as electron transport material for said device.
